(19) United States
(12) Patent Application Publication
(10) Pub. No.: US 2026/0151793 A1
(43) Pub. Date: Jun. 4, 2026

(54) METHODS AND APPARATUS FOR THERMAL PROCESSING OF MATERIALS

(71) Applicant: PulseForge, Inc., Austin, TX (US)

(72) Inventors: Rudresh Ghosh, Austin, TX (US); Vahid Akhavan Attar, Austin, TX (US); Ara W Parsekian, Georgetown, TX (US)

(21) Appl. No.: 19/354,436

(22) Filed: Oct. 9, 2025

Related U.S. Application Data
(60) Provisional application No. 63/705,291, filed on Oct. 9, 2024.

(51) Int. Cl. B05D 3/02; H01L 21/67; H01L 21/677; H01L 21/687

(52) U.S. Cl. CPC B05D 3/0263; H10P 72/0602; H10P 72/3311; H10P 72/7618

(57) ABSTRACT

Apparatus and associated methods for thermally processing sets of items are disclosed. An illuminator illuminates a first set of items to thermally process the first set of items. To permit the illuminator to illuminate the full scope of the first set of items, the illuminator is moved relative to the first set of items and/or the first set of items is moved relative to the illuminator. Heat from an illuminated first item is transferred to a second item not yet illuminated. To account for the preheating of the second item, illumination of the second item is adjusted relative to illumination of the first item.

### CROSS-REFERENCE TO RELATED APPLICATIONS

This application claims the benefit of U.S. Provisional Application No. 63/705,291, filed Oct. 9, 2024, which is hereby incorporated herein by reference in its entirety.

### FIELD

The present disclosure generally relates to thermal processing and more particularly to apparatus and methods for performing thermal processing of materials.

### BACKGROUND

Pulsing flashlamps can be used to thermally process one or more sets of items comprising thermally processable material. For example, a pulsing flashlamp can be used to thermally cure material, to dry material, to debond material, etc. For example, U.S. Pat. No. 8,410,712 discloses a flashlamp used to cure a thin film on a substrate moved on a conveyor past the flashlamp.

### SUMMARY

In one aspect, a photonic processing apparatus is configured to achieve substantially uniform thermal processing of at least a first set of items. The photonic processing apparatus comprises a first mobile support configured to support the first set of items in a first item arrangement in which the items span a first distance. The first mobile support is configured to support the first set of items in the first item arrangement for thermally processing the first set of items. The photonic processing apparatus additionally comprises an illumination system configured to emit a plurality of illumination pulses in an illumination area. The illumination area has an illumination span that is less than the first distance. The photonic processing apparatus further comprises a control system comprising a photonic processing controller operatively connected to the illumination system. The control system additionally comprises a tangible, non-transitory storage medium operatively connected to the photonic processing controller. The tangible, non-transitory storage medium stores controller-executable instructions configured to, when executed by the photonic processing controller, operate the illumination system to emit a plurality of illumination pulses to thermally process the first set of items as a position of the first set of items changes relative to the illumination system in a travel direction that corresponds to the illumination span of the illumination area to thermally process an entirety of the first set of items with the plurality of illumination pulses. The operation of the illumination system is controlled as a function of a temporal heating characteristic associated with heat transfer through the mobile support to the first set of items upstream of the illumination area.

In another aspect, a method of photonically processing a set of items comprises providing a first mobile support configured to support the first set of items in a first item arrangement in which the items span a first distance. The first mobile support is configured to support the first set of items in the first item arrangement for thermally processing the first set of items. The method further comprises providing an illumination system configured to emit a plurality of illumination pulses in an illumination area. The illumination area has an illumination span that is less than the first distance. The method additionally comprises changing a position of the first set of items relative to the illumination system in a travel direction that corresponds to the illumination span of the illumination area. The method also comprises using the thermal illumination system to emit a plurality of illumination pulses to thermally process an entirety of the first set of items with the plurality of illumination pulses. The illumination system is operated as a function of a temporal heating characteristic associated with heat transfer through the mobile support to the first set of items upstream of the illumination area.

Other objects and features will be in part apparent and in part pointed out hereinafter.

### BRIEF DESCRIPTION OF THE DRAWINGS

FIG. 1 is a schematic diagram of thermal processing apparatus in accordance with one aspect of the present disclosure;

FIG. 2 is a schematic diagram of a control system of the apparatus of FIG. 1;

FIG. 3 is a schematic of the thermal processing system of FIG. 1 indicating a transient heat propagation phenomenon;

FIG. 4 is a schematic diagram of a thermal processing apparatus in accordance with another aspect of the present disclosure;

FIG. 5 is a schematic diagram of a control system of the thermal processing system of FIG. 4; and

FIG. 6 is a schematic of the thermal processing system of FIG. 4;

FIGS. 7A-7C are flow diagrams showing an example process for operating the thermal processing system shown in FIGS. 4-6.

Corresponding reference characters indicate corresponding parts throughout the drawings.

### DETAILED DESCRIPTION

In one aspect of the present disclosure, photonic processing can be used in a variety of ways to thermally process a thermally sensitive material carried on one or more electronics manufacturing structures. For example, the one or more electronics manufacturing structures can be a laminated stack comprising a carrier (broadly, a mobile support, e.g., a tray or a rigid body formed of glass, silicon quartz, etc. or a flexible web comprising paper, film, etc.) and one or more electronics structures (e.g., one or more electronics devices, such as a chip, a wafer, a film, or other related structures, and/or one or more components of an electronics device) carried on the carrier. One or more materials that can be photonically processed may be present on each of the electronics structures carried on a respective stack. One example of a photonic processing material is an adhesive used to temporarily bond the electronics structure to the carrier. The adhesive can be thermally stable at temperatures up to a threshold debonding temperature which can be reached in a photonic debonding process. Alternatively, the photonic processing material can comprise one or more electronics substrates (e.g., a wafer, a film, etc.) carried on the carrier and/or component electronic materials for electronics substrates (e.g., a semiconductor or metal layer, solder, etc.). The electronics manufacturing structures described herein can be supported by a support such as a platform, a holder, a tray, a conveyor, etc.

In general, a flashlamp head (broadly, an illuminating element in an illumination system) is controlled to provide a flash or pulse of processing light to heat some (e.g., a subset of) or all of the photonic processing material via photonic processing. In some examples, the processing material may have light-absorbing characteristics for generating heat upon direct exposure to the processing light. In other examples, the processing material may be positioned near (e.g., adjacent) a light-absorbing layer configured to generate heat upon exposure to the processing light and transfer the generated heat to the material.

The flashlamp head can comprise one or more flashlamps (e.g., bulbs, light emitters, etc.) which, when energized, emit broadband, incoherent light that can reach a broad target processing area with a relatively uniform power profile or radiant exposure over the entire exposed area. For example, the flashlamp head can be configured to expose at least an entire width of a 300 mm wafer to each pulse of light. The flashlamp head can be used in conjunction with a conveyor support to process moving electronics manufacturing structures, e.g., by synchronizing pulses of light to the moving electronics manufacturing structures. Alternatively, the flashlamp head can be configured to be moved relative to one or more stationary electronics manufacturing structures (e.g., by being mounted to a moving arm). The relative movement of the electronics manufacturing structures and the flashlamp head allow for convenient processing of relatively large electronics manufacturing structures.

For example, the flashlamp head can be pulsed multiple times to expose discrete or overlapping portions of a respective electronics manufacturing structure (broadly comprising multiple subsets of processing material, such as layers of material in multiple electronics structures carried in a row on a common carrier structure, which define discrete exposure zones for processing) to facilitate the efficient and comprehensive processing of material that spans an overall processing area that is larger than an exposure area of individual pulses of light from the flashlamp head. The flashlamp head illuminates a first subset of material in a first pulse of light in the illumination region (or illumination area), a second subset of material in a second pulse in the illumination region, etc., until all subsets of the targeted material in the entire electronics manufacturing structure have been processed zone-by-zone. The synchronized movement of the flashlamp head and electronics manufacturing structures may be continuous or discontinuous. The sequential pulsing of the flashlamp head can be utilized to process a large, continuous layer of material and/or multiple discrete material elements spaced apart on one electronics manufacturing structure. After a complete set of material has been processed, subsequent (second, third, fourth, and so on) sets of material may be processed in the same or a similar way. In other words, from one set of material to the next, the types of electronics manufacturing structures and materials used therein (e.g., configuration, makeup, shape, etc.) can vary. As explained in further detail below, preset instructions, or recipes, for illuminating a particular set of material can vary among the subsets of material, and the recipes can vary from one set of material to the next.

An example of a synchronized system for curing film material on a moving conveyor is provided in U.S. Pat. No. 8,410,712, the contents of which are hereby incorporated herein by reference in their entirety. It will be appreciated, however, that photonic processing should be understood broadly to encompass a variety of operations for different types of materials in electronics manufacturing structures, including without limitation curing, sintering, soldering, bonding (e.g., hybrid bonding), and debonding. Relatedly, it will be appreciated that electronics manufacturing structures should be understood broadly to encompass a variety of structures that can be used with the flashlamp head for photonic processing, including without limitation single-wafer bonded stacks, continuous film structures, and carrier structures on which multiple discrete electronic devices or components are carried.

As explained in further detail below, the equipment, methods, and processes described herein provide specific improvements to various challenges can arise in photonic processing of one or more electronics manufacturing structures when an active illumination area (e.g., beam area) of a flashlamp head does not fully cover a processing area of the materials to be heated by the flashlamp in a processing cycle. When such electronics structures are subjected to sequential (e.g., overlapping or non-overlapping) thermal processing cycles, thermally conductive material in each respective electronics manufacturing structure and/or in the support structures used therewith tends to cause global heat transfer within the electronics manufacturing structure. For example, when a first pulse illuminates a first exposure zone to process a first subset of material in the first zone, thermal energy generated in adjacent areas of the electronics manufacturing structure is transferred via the thermally conductive material to portions of the electronics manufacturing structure in subsequent or “upstream” areas (e.g., a second exposure zone to be processed after the first zone). Accordingly, one or more of the subsets of material not yet illuminated (e.g., not yet processed in an illumination exposure zone, such as not yet moved under or passed over a flashlamp head) may be heated via conduction due to thermally conductive material conducting heat upstream relative to the illumination exposure zone. Accordingly, material upstream of the illumination is preheated and, if the preheating is not accounted for, results in the preheated material being thermally processed by the designated illumination more than desired. In an aspect of the present disclosure, the system is operated to compensate for preheating of upstream material such that such preheating does not result in more than desired thermal processing. For example, recipe-based thermal processing is implemented in a non-uniform manner, accounting for upstream preheating, to accomplish more uniform thermal processing of the illuminated material overall based on temporal heating characteristics that can be accounted for in calibration sequences in advance of the recipe-based photonic processing cycle or adjusted in real-time as a function of feedback obtainable after each pulse.

A thermal processing system of the present disclosure can include a flashlamp system (broadly, illumination system), an illuminated material support (for supporting the material to be illuminated), and a thermal processing control system. The flashlamp system includes an illumination head comprising a flashlamp (broadly, illuminator) including one or more light sources (e.g., lamps, etc.). The flashlamp head can be moveable with respect to the illuminated material support. Desirably, the flashlamp is configured to emit incoherent light in a broadband wavelength spectrum including at least light in the visible light spectrum. The flashlamp is configured to emit a beam of light having a beam width (e.g., an illumination span) to permit the flashlamp to illuminate an illumination area to illuminate one or more exposure zones (e.g., corresponding to one or more subsets) of the material to be thermally processed.

The illuminated material support (broadly, illuminated material support system) is configured to locate material to be illuminated by the illumination system. The illuminated material support can comprise a conveyor, a robot, a platform, a table, or a bed, etc. The illuminated material support system may or may not include an illuminated material holder, such as a tray, a plate, or a container, etc. configured to be moveable with and carried by the material support.

The thermal processing control system comprises a thermal processing system controller (e.g., processor) and a non-transitory tangible storage medium storing instructions executable by the thermal processing system controller. For example, the thermal processing system controller can include an illumination system controller and an illuminated material support system controller. The instructions stored on the tangible storage medium represent functional aspects of the thermal processing system, such as for executing functions disclosed herein. The tangible storage medium can comprise one or more tangible storage mediums, such as an illumination system tangible storage medium and/or an illuminated material support tangle storage medium. The thermal processing control system can include a user interface comprising a user input (e.g., actuators, buttons, keyboard, microphone, mouse, etc.) and a user output (e.g., display, screen, speaker, or other audio/visual output). The thermal processing control system comprises a thermal sensor configured to sense thermal information upstream of the illumination exposure zone (e.g., a temporal heating characteristic of material upstream of the illumination exposure zone). For example, the thermal sensor can comprise a pyrometer configured to provide rapid temperature data corresponding to a surface temperature of material in an upstream zone in sequence with pulses of light from the illumination system. Moreover, one or more position sensors and/or speed sensors (e.g., associated with the illumination head and/or illuminated material support, such as an encoder) can be provided to provide location data (e.g., representative of location of the illuminator, the material support, the material holder, and/or the material, etc.) to the tangible storage medium and/or the thermal processing system controller. As a function of the data, operation of the thermal processing system is modified to adjust thermal processing for subsequent illumination pulses. For example, subsequent movement of the illuminator and/or illuminated material support system can be adjusted for upstream material to account for the preheating of the upstream material. Additionally or in the alternative, operation of the illumination system can be adjusted to illuminate the upstream material differently from illumination of the downstream (already flashed) material. For example, fewer pulses or flashes may be used per increment of material, or an illumination intensity for each pulse can be reduced or increased in accordance with recipe-bound instructions and/or real-time feedback response. Other settings of the illumination system can be modified or adjusted to compensate for the preheated material. In general, for upstream material that has been preheated by earlier pulses, an average illumination energy applied in subsequent illumination pulses corresponding to the exposure zones farther upstream tends to be less than an average illumination energy applied to farther downstream exposure zones in the prior illumination pulses to account for upstream preheating that generally occurs with each successive pulse. Various system settings, such as flash duration, time between flashes, speed of relative movement of the material and flashlamp, etc., can be adjusted, based on the thermal information indicating upstream preheating, to provide uniform thermal processing of the upstream preheated material relative to the downstream material and to achieve a desired overall outcome of the thermal processing for the material as a whole.

It will be appreciated that one or more components of the thermal processing control system can be integrated in a thermal processing unit (e.g., including the illumination system and/or the illuminated material support system), and one or more components thereof can be distributed or remote relative to the thermal processing unit.

The thermal processing control system can process and/or store sensed thermal data and position/location data associated with multiple exposure zones for one or more respective materials (broadly, thermal profiles) in one or more executed processing sequences, and/or the thermal processing control system can store operational parameters associated with the relative movement of the illuminator and the illuminated material support in each of the one or more executed processing sequences. The thermal processing control system can associate the thermal profiles with the recipes to generate historical data which can be applied in subsequent processing operations for sets of similar material (e.g., multiple electronics manufacturing structures with identical materials in an identical configuration). When the thermal processing system is used for thermal processing of additional (e.g., successive) sets of material having temporal heating characteristics that can be correlated with stored historical data, the system can be operated as a function of the stored historical data to apply non-uniform illumination across the set of material to regulate an overall processing energy applied in each exposure zone for optimized (e.g., substantially uniform) thermal processing performance.

In some implementations, the stored historical data can be used in combination with real-time data (e.g., thermal data and/or position/location data) to implement real-time feedback controls for the system when executing recipe-based thermal processing operations. In other implementations, the stored historical data can be relied on as a preset calibration for recipe-based thermal processing operations without implementation of real-time feedback controls. It will be appreciated that the thermal sensor, position sensor, and/or speed sensor may therefore be used effectively in several different ways, including for implementing a one-time calibration sequence for a recipe associated with particular set of processing materials, for providing real-time feedback controls while executing the corresponding recipe (instead of or in addition to a calibrated sequence for the corresponding recipe), and/or for generating iterative historical data for self-improving calibration parameters for the corresponding recipe (e.g., modifications and/or updates to the recipe).

In one example, the thermal processing system is capable of identifying what type of material is to be thermally processed (e.g., what set of material is being presented for illumination), or the user provides identifying information to the system (e.g., via the user input), to permit the system to select and implement an appropriate stored thermal processing recipe. For example, the set of material may be supported by a material holder having indicia (e.g., RFID tag or other indicator) identifiable (e.g., readable) by the illumination system (e.g., RFID reader thereof) to identify the material to be illuminated. As another example, the thermal processing system may store a database of illumination material identification information (e.g., images of illumination material) against which the thermal processing system compares a currently presented set of material for thermal processing (e.g., via image comparison based on an image obtained from image sensor of thermal processing system) to identify the material to be illuminated. It will be appreciated that the tangible storage medium stores instructions executable by the thermal processing system controller for performing such functions.

### Photonic Processing Generally

Photonic processing uses illumination pulses from a flashlamp to heat a thin film or component on a substrate via absorption of the illumination pulses from the flashlamp. The illumination pulses can be generated by initially charging a capacitor bank up to a predetermined voltage by using a capacitor bank charging power supply, followed by discharging a current across a flashlamp. A gas in the flashlamp (e.g., sub-atmospheric xenon or krypton) is resistively heated by the current discharge and subsequently emits light according to its composition and temperature. When a reflector is placed on one side of the lamp, the light can be guided to facilitate illumination of material in a corresponding exposure zone. Each illumination pulse is absorbed by the illuminated material, resulting in localized heating around the illuminated material in (and around) the corresponding exposure zone.

### Pulse-Forming Network Method

The intensity and duration of the illumination pulses (and other related parameters) can be regulated as control variables for processing material in various manufacturing processes, e.g., photonic curing. The control variables can be adjusted to adjust a processing energy associated with each illumination pulse. The total energy stored in the capacitor bank can be controlled by changing the charging voltage on the capacitor bank. To control the pulse length of the light emitted, an inductor can be placed in series with the capacitor bank and the flashlamp to form a serial pulse forming network (PFN). When the PFN is critically or overdamped, there is a characteristic pulse length of the emission from the flashlamp, and it may be switched using a silicon controlled rectifier (SCR). When one desires to change the pulse length, the system may be powered down, and an inductor of a different value may be substituted for the first inductor. Although increased charging voltage on the capacitor bank generally increases the intensity of the emission for a given inductance value, changing the inductance value also tends to change a peak intensity of the illumination pulse along with the pulse length. Thus, when the serial PFN method is used, it will be appreciated that peak intensity and pulse length are not independently controllable.

### Modulation Method

As an alternative to the PFN approach, the pulse length may be controlled by actively switching the current to the flashlamp on and off. This may be accomplished by using an insulating gate barrier transistor (IGBT) as a switch. In contrast to the PFN method, no additional inductance is placed in the system, and the pulse length may be electronically controlled, e.g., the flashlamp may be switched on and off with arbitrary timing. This means that as long as there is adequate capacitance and voltage on the capacitor bank, the latter of which is supplied by a charging power supply, the pulse length can be arbitrarily changed on the fly and without powering down.

In addition to the pulse length, the frequency of firing the flashlamp can be electronically and arbitrarily changed as well. Also, unlike the PFN method, the intensity of the discharge is a monotonically increasing function with the charging voltage. Thus, with the modulation approach, peak intensity and pulse length can be independently controlled. Provided the capacitor bank charging power supply has adequate capacity to charge up the capacitor bank to the same voltage before each firing, the pulse frequency can also be independently controlled. With the PFN method, an entire supply of the capacitor bank is generally depleted with each discharge. With the modulation method, discharge patterns can be more flexible. For a given charging voltage, only a portion of the capacitor bank may be discharged. When the modulation method is used, more energy is generally transferred to the processing material with each illumination pulse, and each pulse can be sustained as the length of each illumination pulse is extended.

### Methods of Illuminating an Area Larger Than Illuminator Exposure Area

When it is desired to process an area larger than the illumination exposure area associated with an illuminator (e.g., a beam area of a flashlamp head), the illuminator must be pulsed more than once over two or more discrete exposure zones to process all material in the larger area. As indicated above, there are generally two approaches for configuring the system to control a plurality of illuminating pulses that cover a processing area defined by two or more overlapping or non-overlapping exposure zones.

The first approach is to index the processing material relative to the illuminator in a stepwise pattern after each illumination pulse to expose unprocessed zones to the illuminator (e.g., the illumination region) for subsequent illumination pulses. For example, this “step and flash” sequence can be implemented with a conveyor support that is configured to move a processing material set in short steps that correspond to respective exposure zones in accordance with a corresponding recipe associated with the processing material. The conveyor movements are repeated until the entire set of material is processed. The second approach involves continuously conveying the processing material relative to the illuminator while illumination pulses are applied. In the second approach, recipes and historical data can be used to synchronize illumination pulses with a continuously moving conveyor support. In the second approach, several illumination pulse parameters associated with each illumination pulse, e.g., intensity and duration are adjusted to correspond to designated exposure zones for a controlled illumination pulse pattern. It will be appreciated that various combinations of the first and second approaches may be used in some circumstances without departing from the scope of the present disclosure.

### Overlap Factor

In accordance with the above approaches, it will be appreciated that more than one illuminating pulse may be provided by the illuminator in a controlled sequence, resulting in an overlapping or non-overlapping pattern of illuminating pulses for fully processing the processing material. In situations where overlapping pulses are created (e.g., when the second approach is calibrated to provide illumination pulses to cover multiple overlapping exposure zones, an overlap factor (OLF) may be introduced to ensure that substantially all zones of processing material are exposed to a comparatively consistent amount of processing energy. The OLF is a dimensionless term and signifies an average number of light pulses associated with a unit distance of travel of the processing material. Mathematically, one can connect the overlap factor, the length of the beam in the conveyance direction, and the conveyance speed, as follows:

$$OLF = pulse frequency / ( conveyance speed / beam width ) .$$

In practical units:

$$OLF = 0.6 f w / v$$

where:
f is pulse frequency in pulses/second;
v is relative conveyance speed (broadly, movement speed) between material and flashlamp head in meters/minute; and
w is the flashlamp beam width (or illumination span) in the conveyance direction in cm.

In a flashlamp head assembly, beam width may be defined as the geometric dimensions of an optical aperture of the flashlamp head, but it may also be defined as a Full Width Half Max (FWHM) of the beam produced by the flashlamp head, a 95% peak power level of the beam, or another selected metric to define suitable overlap. The OLF should be understood as an adjustable parameter (as opposed to a constant), as explained in greater detail below, and therefore can be calculated in accordance with differing metrics suitable to particular equipment, thermal performance characteristics of the items being processed, and/or operating parameters. For example, the constant multiplier may be changed as a function of the kind of material being processed in sets or batches.

When the first and second methods are being used together, one may synchronize the pulsing of flashlamp with the conveyance rate to facilitate a constant overlap factor. The resulting synchronization enables a repeatable energy deposition independent of the conveyance rate. However, numerous industrial processes do not have a constant conveyance rate, and/or the rate may not be easily ascertained without additional sensors, such as an encoder configured to electronically feed signals associated with conveyor speed to the control system. Therefore, in a recipe-based illumination sequence, it will be appreciated that data associated with the encoder may be used in a function for determining an illumination pulse period and duration to maintain a constant OLF as an alternative to other metrics that could be used to estimate a motor speed (e.g., motor voltage).

It will be appreciated that the implementation of an OLF may facilitate embodiments of the present disclosure but can be omitted and/or substituted without departing from the scope of the present disclosure.

### Example Embodiments

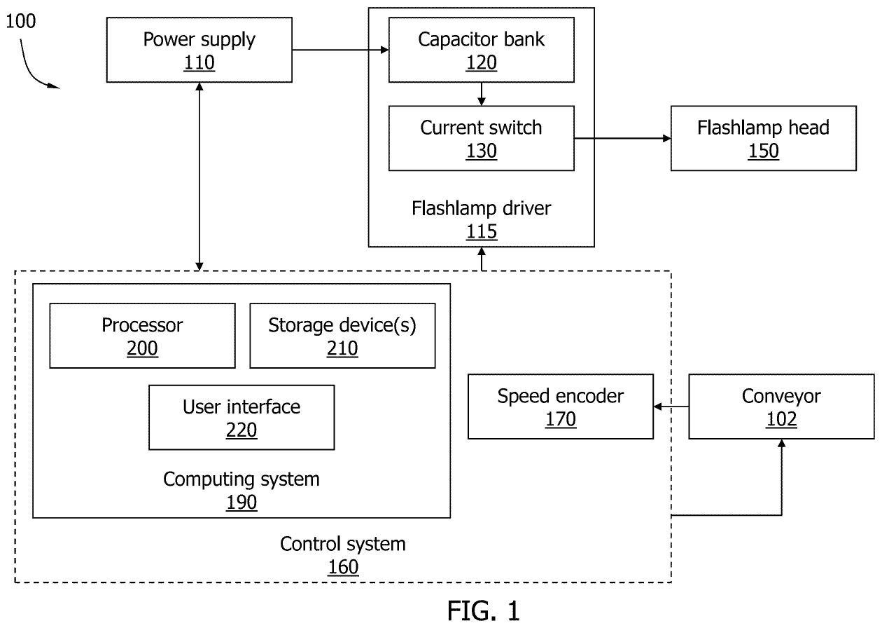

Referring now to the drawings, and in particular to FIG. 1, there is depicted a block diagram of a photonic processing apparatus for performing thermal processing of one or more electronics manufacturing structures according to one example. As shown, an photonic processing apparatus 100 broadly includes a conveyor 102, a capacitor-bank-charging power supply 110, a flashlamp driver 115 comprising a capacitor bank 120 and a current switch 130, a flashlamp head 150 comprising one or more flashlamps, and a control system 160 operated by a computing system 190. The control system 160 is configured to activate the operational equipment of the photonic processing apparatus 100. It is contemplated that the computing system 190 includes a photonic processing controller 200 and one or more storage devices 210 (broadly, tangible, non-transitory storage mediums) operatively coupled to the photonic processing controller in accordance with principles that are well-known to those skilled in the art. The computing system is operatively connected to a user interface 220 configured to receive input from a user. For example, a user can input various operating parameters for the control system, including parameters for recipe-based operation as described in greater detail below. The control system 160 is operatively coupled to the conveyor 102, the power supply 110, the flashlamp driver 115, and one or more sensors (e.g., a speed encoder 170, a pyrometer 185, and/or position sensors 180, as described in greater detail below) to define a special-purpose control system for carrying out the functions associated with the thermal processing control system described above. The capacitors in capacitor bank 120 are, for example, electrolytic capacitors. The current switch 130 comprises an IGBT device, though other switches, such as an SCR could also be used.

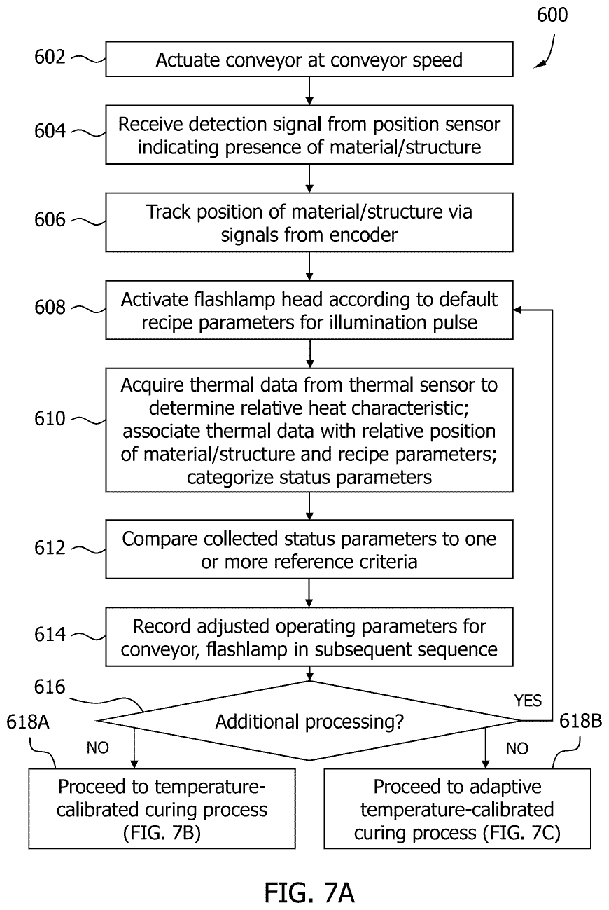

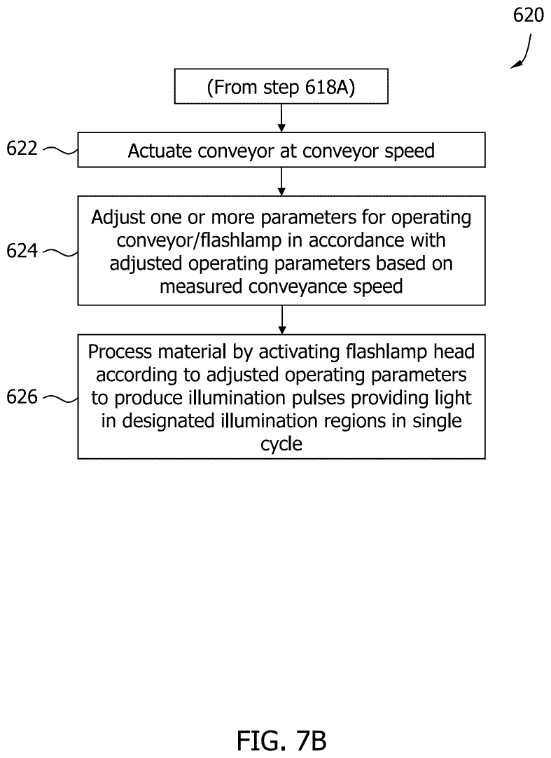

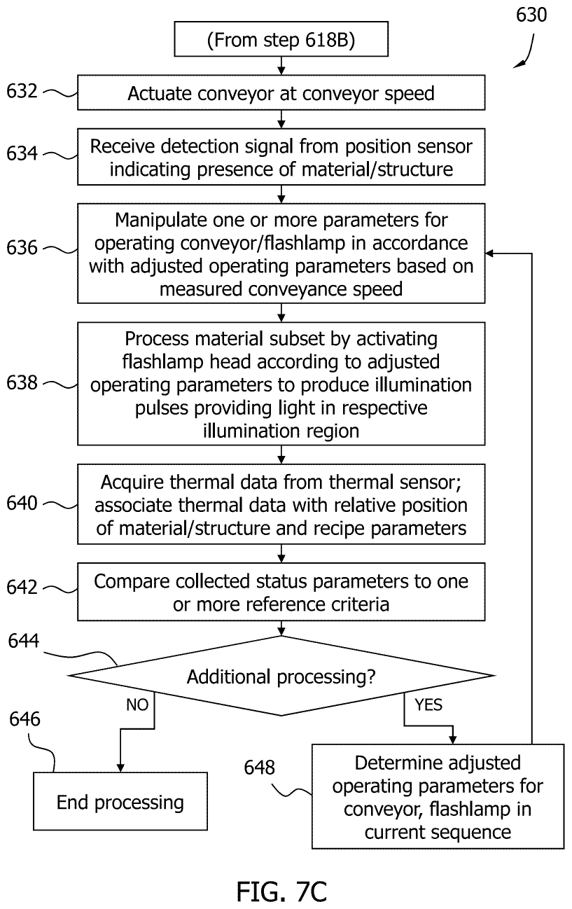

Although the flashlamp driver 115 is generally described as a combination of the capacitor bank 120 and the current switch 130, it will be appreciated that the flashlamp driver 115 may be integrally formed or may be a looser composite of the two component structures. The capacitor bank 120 is configured to be charged by the capacitor-bank-charging power supply 110. The flashlamp driver 115 is operatively connected to the flashlamp head 150 so that charges from the capacitor bank 120 can be discharged to the flashlamp 150 via the current switch 130, for example, in a repeated on-and-off cycle initiated by the control system 160 in discharge cycle with a controlled (e.g., modulated) frequency. The repeated switching of the current switch 130 modulates the electrical current flowing from the capacitor bank 120 to the flashlamp head 150, which in turn switches the flashlamp(s) of the flashlamp head 150 on and off in a corresponding cycle, resulting in a series of several sequential illumination pulses. In the present example, the frequency or pulse length of the illumination pulses emitted by the flashlamp(s) of flashlamp head 150 is dictated by the control signals output by the control system 160. Further details of operational sequences executed by the control system 160 to generate illumination pulses are described below in connection with FIGS. 7A-7C.

Referring still to FIG. 1, the apparatus 100 can include sensors, for example, a speed encoder 170 (broadly, a speed detector). The speed encoder 170 facilitates a synchronization process for illumination pulses as a function of conveyance speed and independent of conveyor input parameters like an operating voltage or a PWM duty cycle for a conveyor motor. The one or more flashlamps of the flashlamp head 150 are configured to facilitate a generally uniform thermal processing profile for material conveyed past the flashlamp head 150, e.g., due to a minimal variance in beam intensity of the illumination pulses emitted by the one or more flashlamps. Beam uniformity facilitates a more uniform temperature-over-time profile across all portions of an electronics manufacturing structure conveyed past the flashlamp head 150, though it will be appreciated that variations in material, and varying thermal characteristics associated therewith, can result in variations in a corresponding thermal profile, which the systems, methods, and processes described herein seek to mitigate.

Although the encoder 170 facilitates the calculation of a constant overlap factor and improved synchronization for repeated illumination pulses independent of an input conveyance rate, the materials in an electronics manufacturing structure can still have complex thermal characteristics that cannot be addressed by more accurate speed readings alone. As discussed above, since each illumination pulse is separated from subsequent pulses by a small amount of time, the heat generated by each illuminating pulse dissipates through the materials in the electronics manufacturing structure and, potentially, through the conveyor that supports the electronics manufacturing structure and into other portions of the electronics manufacturing structure (e.g., upstream portions of the electronics manufacturing structure to be illuminated by subsequent illumination pulses). The heat dissipation phenomenon from multiple illumination pulses in sequence creates a variable temperature-over-time profile in successive exposure zones, with the later-illuminated zones experiencing comparatively higher processing temperatures if the illumination pulses are maintained at a substantially constant intensity.

Although it is generally possible to synchronize multiple overlapping illumination pulses to provide multiple instances of full exposure to all portions of processing materials during an illumination cycle, it will also be appreciated that geometric optics provide another potential implementation of the OLF. In practice, flashlamp heads do not produce illumination light with perfectly defined (e.g., sharp) beam edges. Because the intensity of illumination light falls off near the edges of each processing zone, beams of illumination light can be slightly overlapped to achieve a more uniform thermal profile near the upstream/downstream edges of each exposure zone that is similar to a thermal profile near the center of each exposure zone. Additionally, it will be appreciated that an optimal OLF may depend on a complex analysis of the thermal behavior of the materials in each discrete exposure zone. In view of the foregoing, the OLF may be a constant or variable, and the OLF can be an integer or a non-integer. Accordingly, the OLF is best understood as a free or variable parameter that may be adjusted to achieve a desired uniformity when processing of the material. It will further be appreciated that numerous aspects of the system can be adjusted and/or modified independent of the OLF or without reference to an OLF.

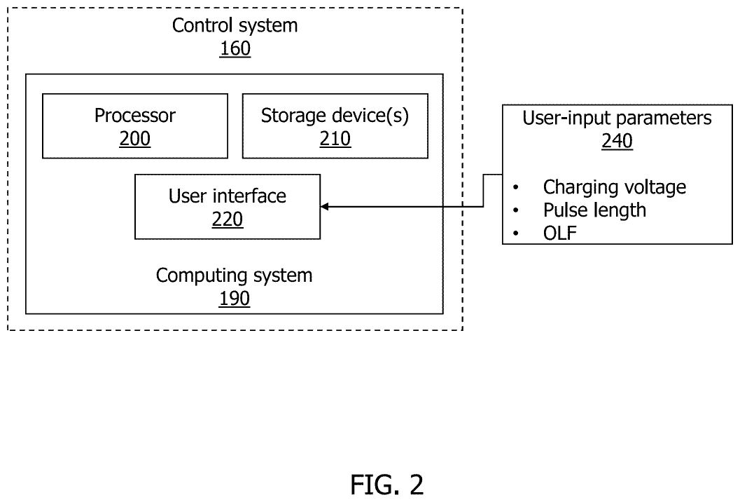

With reference now to FIG. 2, a schematic showing a set of parameters entered into the computing system 190 of FIG. 1 is provided. The user-input parameters are entered via user interface 220. In the present configuration, a user can provide various operating parameters 240, such as a nominal charging voltage for the power supply 110, a pulse length to be pulsed by the current switch 130, and/or a nominal OLF, into the computing system 190 via the user interface 220. The user-input parameters provide a set of instructions for the control system 160 to operate the functional equipment of the system 100 for controlling the conveyor 102 and the flashlamp driver 115 (e.g., by performing operations respective to this hardware). In addition to or as an alternative to inputting the parameters in an item-by-item manner, a qualitative classification for a respective set of materials (e.g., establishing an identity for a particular set of materials associated with one set of operating parameters) can be entered into the computing system 190 with the operating parameters 240, e.g., to classify sets of operating parameters for use in one or more subsequent processing cycles. Each unique set of input operating parameters 240 can be referred to as a recipe which provides instructions for the control system 160 to control the processing of one or more sets of materials to be processed by the system 100 in accordance with the basic operating parameters provided by the recipe. It will be appreciated that a recipe can be pre-programmed and stored in memory 210, in which case entry of a qualitative classification assigned to a corresponding recipe can be used to automatically supply the control system 160 with a preset list of respective operating parameters.

For example, upon entry of a set of parameters 240, the control system 160 can be configured to set the nominal voltage level on the capacitor-bank-charging power supply 110 and instruct the power supply to charge the flashlamp system at designated times to ensure proper operation of the flashlamp driver 115 in accordance with the recipe. During processing, the control system 160 can also sense when the capacitor bank 120 is charged and, once the capacitor bank is determined to be charged, send a control signal to the switch 130 to turn current on and off for the generation of illumination pulses by the flashlamp head 150. The duration of each discharge of current is the pulse length parameter entered as part of the recipe. The pulse frequency, then, is calculated as a function of the OLF, the pulse duration, and the conveyance speed of conveyor 102 (which is measured via speed encoder 170 and may be set nominally by user input). It will be appreciated that a beam width (illumination span) of the illumination pulses emitted by the flashlamp head 150 is generally constant.

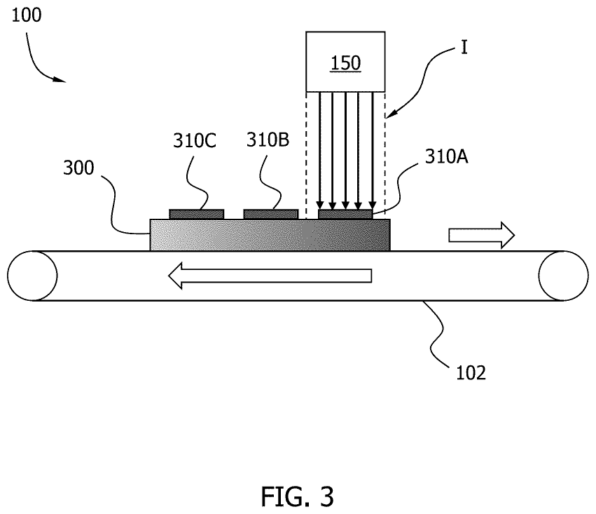

Although the sets of operating parameters 240 entered with each recipe provide a framework for synchronizing illumination pulses emitted by the flashlamp head 150 with a movement speed of the conveyor 102 to normalize an energy output of the flashlamp head relative to materials moved on the conveyor, it will be appreciated that heat transfer phenomena (e.g., heat that travels upstream relative to an illumination area) can still affect processing uniformity across spaced-apart sets of material during coordinated sequences of illumination pulses. Referring now to FIG. 3, there is shown a scenario in which three subsets of material 310A, 310B, and 310C (e.g., electronic device wafers) are carried by a carrier 300 (collectively, an electronics manufacturing structure) and conveyed on a conveyor 102 to be processed by the flashlamp head 150 via exposure to high-intensity illumination pulses. In the present example, a relatively high OLF is selected (e.g., an OLF of greater than 2.0) such that all portions of the material 310A-310C are exposed to two or more successive pulses of light in photonic processing cycle. A substantial amount of energy is deposited into the material subset 310A via a first series of illumination pulses (e.g., at least two pulses to heat the material subset 310A). Light from the illumination pulses may additionally be absorbed by light-absorbing portions of the carrier 300 and conveyor 102 in illumination exposure zones associated with each respective illumination pulse.

In situations where the carrier 300 comprises a material with at least some thermal conductivity, some of the heat generated by the first series of illumination pulses to process the material subset 310A is rapidly dissipated through the carrier 300. As shown with corresponding arrows in FIG. 3, the heat generally propagates through the carrier 300 in an upstream direction (longer arrow) opposite a conveyance direction (shorter arrow) associated with the conveyor 102. The heat diffuses within the carrier 300, and, when the heat reaches material subsets 310B, 310C that are not yet illuminated by flashlamp 150, the subsets of material are heated above a starting temperature for the first material subset. This preheating, combined with the same average power from flashlamp 150 results in a relative overheating of material 310 on the trailing edge of a discrete carrier 300. Thus, a uniform radiant power deposition described above does not necessarily result in uniform thermal processing of material 310.

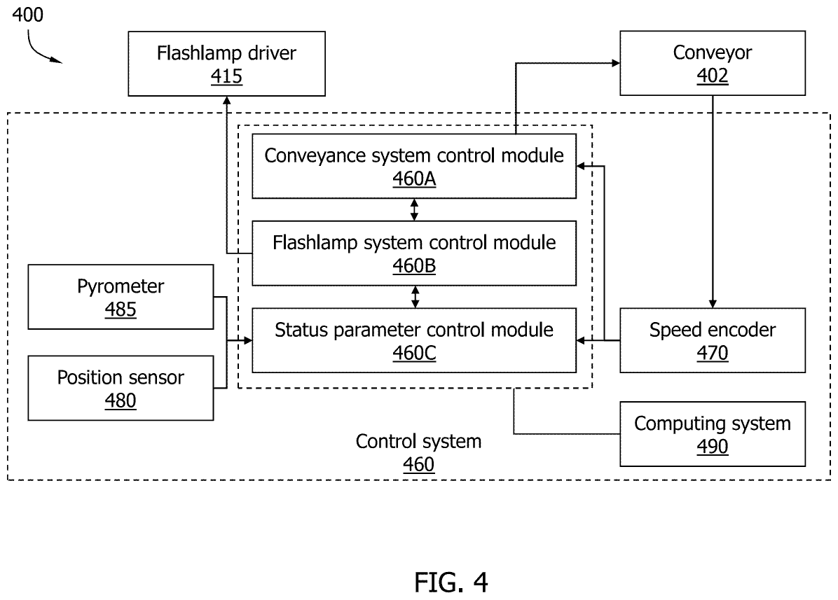

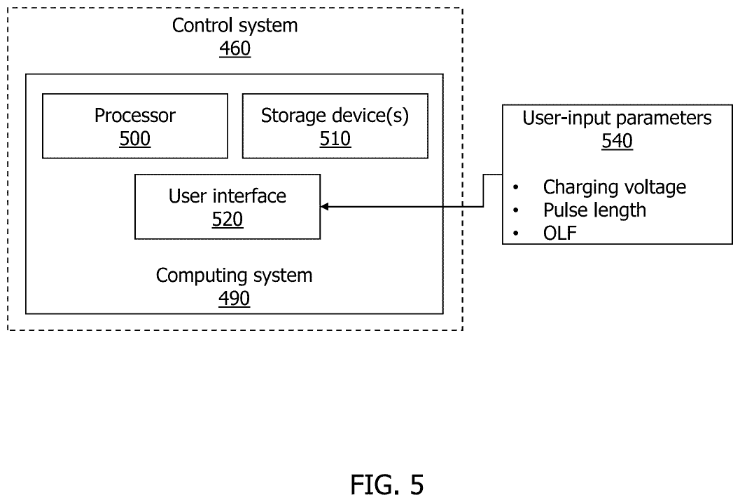

With reference now to FIGS. 4-6, a photonic processing apparatus 400 is shown that is optimized to overcome the challenges of processing uniformity presented above in connection with FIGS. 1-3 by normalizing a thermal profile of sets of material processed in sequence on a single support. The photonic processing apparatus 400 broadly includes a conveyor 402, a capacitor-bank-charging power supply 410, a flashlamp driver 415 comprising a capacitor bank 420 and a current switch 430, a flashlamp head 450 comprising one or more flashlamps, and a control system 460 operated by a computing system 490. As can be seen in FIG. 5, the control system 460 can comprise several dedicated control modules (e.g., a conveyance system control module 460A, a flashlamp system control module 460B, and/or a status parameter detection module 460C) configured to activate the operational equipment of the photonic processing apparatus 400 and process feedback data associated with the operation of the apparatus 400. It is contemplated that the computing system 490 includes a photonic processing controller 500 and one or more storage devices 510 (broadly, tangible, non-transitory storage mediums) operatively coupled to the photonic processing controller in accordance with principles that are well-known to those skilled in the art. The computing system 490 is operatively connected to a user interface 520 configured to receive input from a user. For example, a user can input various operating parameters 540 for the control system, including parameters for recipe-based operation as described in greater detail below. The control system 460 is operatively coupled to the conveyor 402, the power supply 410, the flashlamp driver 415, and one or more sensors (e.g., a speed encoder 470, a pyrometer 485, and/or position sensors 480, as described in greater detail below) to define a special-purpose control system for carrying out the functions associated with the thermal processing control system described above. The capacitors in capacitor bank 420 are, for example, electrolytic capacitors. The current switch 430 comprises an IGBT device, though other switches, such as an SCR could also be used.

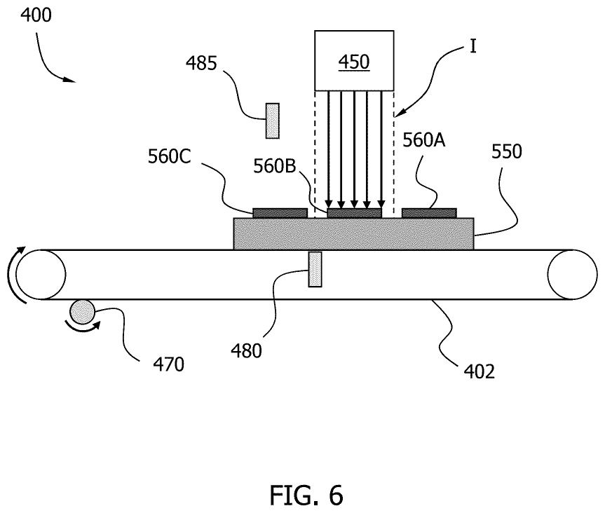

As best seen in FIG. 6, a position sensor 480 (e.g., a threshold crossing detector and more broadly a kind of position detector) is utilized to detect when a carrier 550 crosses a threshold point on conveyor 402 (broadly, a conveyor system) prior to any material being processed by the flashlamp head 450. When data from the position sensor 480 is processed in combination with data from the speed encoder 470, the position of carrier 400 can be known during its entire processing time. As an alternative to speed encoder 470 and a threshold crossing detector (e.g., to extrapolate a relative speed and position of the material at various times), one or more absolute position sensors for detecting discrete locations of carrier 550 can be used to generate position and/or conveyance speed data. Alternatively, an imaging device can be used with image processing equipment to extrapolate a position and speed of the material.

A pyrometer 485 is placed upstream of flashlamp head 450 (relative to a conveyance direction of the conveyor) outside of the illumination region I (broadly, an illumination area) to measure the temperature of an upstream portion of the material 560B-560C and/or carrier 550 as the flashlamp head 450 emits illumination pulses to process material in the illumination exposure zone. Alternatively, pyrometer 485 may be used to sample an average temperature of portions of material 560A-560C (broadly, items constituting a set of items) and/or carrier 550 in the illumination region I while the flashlamp head 450 is used to process a respective portion of the material. It will be appreciated that any radiative emission emitted by the flashlamp head 450 is not detected (and therefore does not interfere with the operation of) the pyrometer 485. As an alternative to the pyrometer 485, an infrared camera may be used. It will be appreciated that an IR camera can be advantageous in that respective temperatures can be measured simultaneously at multiple locations on carrier 550 and/or material subsets 560A-560C. In response to the preheating phenomena experienced in upstream portions of the carrier 550 and/or subsets of material 560B-560C due to downstream photonic processing, signals are sent from the control system 460 to reduce the average power from flashlamp 150 during conveyance to compensate for the preheating of carrier/material 400, 410 from previous upstream processing and establish a more thermally uniform process.

Referring now to FIG. 5, there is shown a control system for the embodiment shown in FIG. 4. In this embodiment, a control system 460 includes a conveyor system control module 460A that interacts with the speed encoder 470 to control movement of the conveyor 402 a flashlamp system control module 460B that interacts with the flashlamp 450 to control the flashes, and a status parameter detection module 460C that interacts with the position sensor 480, pyrometer 485 (more broadly, a thermal sensor), computer 490, and the conveyor system control module and flashlamp system control module to process data for coordinating and optimizing the cross-functionality of the conveyor 402 and the flashlamp 450. The specialized controller structure provides some differences over the embodiment described in connection with FIG. 2. First, both the position and temperature of the material to be processed can be followed while the material is being processed. Additionally, the user can initially enter conveyor system controlling parameters (e.g., conveyance speed) and/or flashlamp system controlling parameters (e.g., voltage, pulse length, and OLF) by entering values into the computing system 490 and/or a user interface used therewith as would be known in the art, but the recipe parameters for controlling the conveyor 402 and flashlamp driver 415 may also be adjusted during processing in response to concurrent position and temperature measurements to facilitate processing uniformity on the material substantially instantaneously. In at least some embodiments, after the optimal charging voltage, pulse length, OLF, or/and speed as a function of the carrier position are determined for a particular processed material, the pyrometer is no longer necessary to further adjust (e.g., dynamically adjust) the controlling parameters during processing cycles. This is because profile information for each of the variables may be stored a memory coupled to the controller (e.g., a database) when repetitively processing one or more known types of materials. Pyrometer 485 may optionally remain active in the system for quality control or for self-adjusting programs, but position detectors are still generally necessary for identifying exactly where multiple carriers 400 (and/or respective processing materials 560A, 560B, 560C) are located relative to the illumination region I during processing. Thus, it will be apparent that the control system is adapted for controlling not only a processing sequence for a single set of materials (e.g., items 560A, 560B, 560C) but for controlling a coordinated processing sequence for multiple sets of materials in different relative positions along the conveyor 402 in the direction of conveyance.

The reduction in the average power during conveyance can be performed by more than one method. Categorically, power modifications may be electronically controlled by the control system by modifying one or more different variables including: OLF (or components thereof), pulse length, charging voltage, and conveyance speed. The average power may be reduced by reducing the OLF during processing. Since the OLF is directly proportional to the total amount of energy that is deposited, a reduction in the OLF while the carrier is passing under the flashlamp can compensate for the preheating of the carrier upstream. Thus, an initial OLF is specified, but the OLF changes during processing.

Another method to reduce the average power emitted by the flashlamp is to reduce the pulse length of the pulses of light from the flashlamp. Like reducing the OLF, it can be done electronically and predictably.

Another method to reduce the average power while processing the material is to reduce the charging voltage. This can be challenging because it generally involves dumping the stored energy in the capacitor bank. However, since the capacitor bank is continually being discharged, one may reduce that charging voltage from the charging power supply during the processing of the material.

Yet another method to reduce the power is to speed up the conveyance versus position under the flashlamp 450. This is desirable in the case when one can control the conveyance speed with control system 460.

It will be appreciated that the control system 460 generally includes one or more processors 500 (individually or collectively a controller) adapted for performing the functions of the conveyance system control module 460A, the flashlamp system control module 460B, and the status parameter detection module 460C. The one or more processors 500 are operatively coupled to a non-transitory tangible storage medium 510 that stores photonic processing (e.g., photonic curing) controller instructions.

An example temperature calibration sequence for the processing of a material (e.g., by photonic curing) is shown in FIG. 7A using reference number 600. The steps of the calibration sequence 600 can be stored as processor-executable instructions in the non-transitory tangible storage medium 510 for execution by the one or more processors 500. First, as shown in block 602, the conveyor 402 is actuated at a first conveyor speed (e.g., a default conveyor speed) in the conveyance direction while a set of processing material comprising subsets 560A, 560B, 560C is loaded on the conveyor while affixed to a corresponding one or more carriers 550. As shown in block 604, when a carrier 500 has reached a threshold point on the conveyor 402 at a location somewhere ahead of the active illumination region I for the flashlamp head 450, a detection signal is transmitted from the position sensor 480 indicating that the carrier 550/material 560A (broadly, any portion of a electronics manufacturing structure conveyed on the conveyor 402) is near the illumination region I. Subsequently, as shown in block 606, the processor 500 tracks (e.g., interpolates) the position of the material 560A-560C and/or carrier 550 relative to the flashlamp head 450 based on conveyor speed data transmitted from speed encoder 470. Once the carrier 550/material 560A-560C reaches the illumination region I associated with the flashlamp 450, the current switch 430 is activated to actuate the flashlamp in a sequence of illumination pulses according to a default constant OLF value while the carrier 550/material 560A-560C advances in the conveyance direction. After each actuated pulse of the flashlamp head 450, thermal data is acquired from the pyrometer 485 to determine a thermal characteristic (or temporal heating characteristic) of the carrier 550/material 560, as shown in block 610. For example, the thermal characteristic can be a temperature reading of an upstream portion of the material 560B shortly after an illumination pulse generates heat in a downstream portion of the material 560A. As is further shown in block 610, the thermal characteristic is associated with other status parameters (e.g., the interpolated position of the flashlamp at the time the thermal characteristic was received) and with other operating parameters of the flashlamp (e.g., the pulse length and/or charge voltage of the previous flash). Then, as shown in block 612, the status parameters associated with each respective illumination pulse can be compared to one or more threshold criteria (e.g., a characteristic processing temperature of the material) stored in the non-transitory tangible storage medium 510 so a modified power level can be calculated based on a difference between the status parameters and the reference criteria for optimizing operation in subsequent illumination cycles. Subsequently, as shown in block 614, the processor 500 can determine one or more adjustments to the operating parameters as a function of the comparisons made in block 612 that can be applied to the conveyor 402 and/or the flashlamp driver 415 during subsequent processing involving the same sets of material. For example, an intensity of illumination pulses can be weakened by a designated factor for downstream processing in accordance with the temporal heating characteristic detected after a corresponding illumination pulses in the sequence. As indicated in block 616, the sequence of blocks 608-614 can be repeated until an entire set of material 560A-560C has been processed. As indicated in blocks 618A and 618B, respectively, it will be appreciated that after the entire set of materials 560A-560C has been processed the calibration depicted in FIG. 7A and blocks 602-614 is complete and the data recorded therefrom can be used in the calibrated processing sequences discussed below in connection with FIGS. 7B and 7C.

An example temperature-calibrated photonic processing sequence (e.g., a photonic curing sequence) based on preset parameters (e.g., a recipe) for processing a material is shown in FIG. 7B with reference number 620. The steps of the temperature-calibrated photonic processing sequence 620 can be stored as instructions in non-transitory tangible storage medium 510 for execution by the one or more processors 500. First, as shown in block 622, the conveyor 402 is actuated at either the first (default) conveyor speed or second (calibrated) conveyor speed in the conveyance direction while one or more processing materials (e.g., 560A-560C) are loaded on the conveyor while temporarily carried by a corresponding one or more carriers 550. As shown in block 624, when a carrier 550 has reached the threshold point on the conveyor 402, a detection signal is transmitted from the position detector indicating that the carrier 550/material 560A is nearby. Subsequently, as shown in block 626, for each illuminating pulse of the flashlamp head 450, the operating parameters for operating the conveyor 402 and/or flashlamp head 450 are manipulated in accordance with the determinations made during the calibration sequence to promote an additional degree of uniformity to the photonic processing sequence and enhance the efficiency and/or consistency of the sequence. As shown in block 626, the material is processed by controlling the switch 430 to activate the flashlamp head 450 and generate illumination pulses in a continuous cycle in accordance with the calibrated operating parameters. As a non-limiting example, an intensity of illumination pulses can be weakened as the successive subsets of material 560A-560C travel through the illumination region I to compensate for progressive heat transfer into upstream portions of the carrier 550.

As an alternative to the temperature calibrated photonic processing sequence 620 discussed above in connection with FIG. 7B, an example adaptive temperature-calibrated photonic processing sequence 630 for processing sets of material is shown in FIG. 7C and can be stored as instructions in non-transitory tangible storage medium 510 for execution by the one or more processors 500. First, as shown in block 632, the conveyor 402 is actuated at either the first (default) conveyor speed or second (calibrated) conveyor speed in the conveyance direction while one or more sets of processing materials 560A-560C are loaded on the conveyor while temporarily carried on a corresponding one or more carriers 550. As shown in block 634, when a carrier 550 has reached the threshold point on the conveyor 402, a detection signal is transmitted from the position detector 480 indicating that the carrier 550/material 560A is nearby. Subsequently, the process enters a loop for each illumination pulse of the flashlamp head 450. First, as shown block 636, the operating parameters for operating the conveyor 402 and/or flashlamp 450 are manipulated in accordance with the determinations made during the calibration sequence to introduce additional uniformity to the curing process and enhance the sequence. Subsequently, as shown in block 638, the flashlamp is flashed in accordance with the calibrated parameters. After the pulse, thermal data is acquired from the pyrometer 485 to determine a new temporal heating characteristic of the carrier 550/material 560B-560C, as shown in block 640. As is further shown in block 640, the temporal heating characteristic is associated with other status parameters (e.g., an interpolated position of the set of material relative to flashlamp at the time the temporal heating characteristic was received) and with other operating parameters of the flashlamp system (e.g., pulse length and charge voltage of the prior flashes). Then, as shown in block 642, the status parameters associated with each respective flash can be compared to one or more reference criteria (e.g., a reference surface temperature of a target material surface after a particular one or more illumination pulses) stored in the non-transitory tangible storage medium 510. For example, the reference criteria can be stored as historical processing metrics in the storage medium 510. In block 644, the processor can be instructed to determine whether additional processing is to be performed, e.g., based on whether all material supported by the conveyor 402 has been processed. In block 646, if no further material requires processing, the sequence ends. If further material requires processing, as shown in block 648, the processor 500 can determine one or more instantaneous adjustments to the operating parameters (e.g., corresponding to a changed illumination pulse intensity, duration, and/or overlap factor) as a function of the comparisons made in block 642 that can be applied to the conveyor 402 and flashlamp 450 during subsequent processing involving the same material configuration. The loop comprising blocks 636 to 648 is repeated until all material has been processed.

It will be appreciated that the tangible storage medium 510 stores instructions executable by the control system 460 to perform the actions described above.

In order to address the non-uniformity of the thermal processing profile across the length of material that is moved relative to an illumination system and processed by illumination pulses, a user may alter the intensity of light from the flashlamp incident on the material over time as a function of the material's translation beneath the exposed region. Such alterations may be accomplished by initially entering the operating parameters for flashlamp processing such as the charging voltage, the length of the pulses of light emitted by the flashlamp, and the average amount of pulses that fall on that material (i.e., an overlap factor) while the material is being conveyed relative to the flashlamp. As a function of status parameters including, for example, the position of the material relative to the flashlamp or a measured temperature of the material or a carrier upon which the material is carried, these three variables may be electronically altered to control an average amount of emissive power from the flashlamp to the material to compensate for in-plane heating of the material upstream during processing. Alternatively, the relative speed of conveyance of the material relative to the flashlamp and/or duration of pulses may be altered as a function of the material's relative position as it passes under the flashlamp while frequency and/or intensity are held constant.

In one aspect, a system for conveying and processing a material by photonic processing includes a conveyor system, a flashlamp system (broadly, an illumination system), and a specialized control system for photonic processing. The control system includes a processor that can broadly include a conveyance system control module, a flashlamp system control module, and a status parameter detection module. The control system can be connected, either by wired or wireless connection, to a peripheral computing device to receive data comprising parameters for operating the control system. The conveyance system control module is configured to actuate the conveyor system to move the material in at least a first direction at a conveyance speed that can be adjusted by the control system either manually or autonomously. The conveyance system control module is operatively coupled to a conveyor actuator that receives a conveyance actuation signal to actuate the conveyor system. The conveyance system control module is additionally operatively coupled to a speed encoder configured to transmit a conveyance speed signal to the conveyance system control module for tracking and regulating the conveyance speed of the conveyor. The control system can additionally be operatively coupled to a position detector configured to produce a detection signal with respect to one or more positions of the material relative to the conveyor. The flashlamp system control module is operatively coupled to a flashlamp driver that is configured to actuate the flashlamp. The flashlamp driver can include a capacitor bank and a current switch. The status parameter detection module is operatively coupled to at least one of the speed encoder or a thermal sensor. The control system is coupled to a non-transitory tangible storage medium that stores photonic processing controller instructions. The photonic processing controller instructions are configured to, when executed by the photonic processing controller, execute a photonic processing operation for material (e.g., a set of material) on the conveyor system by actuating the conveyor system to move the material relative to the flashlamp in a conveyance direction and by periodically pulsing the flashlamp in accordance with an overlap factor of the flashlamp and the conveyor system, wherein the overlap factor is a value derived from the frequency at which the flashlamp is periodically pulsed, a relative velocity of the conveyor system relative to the flashlamp, and a beam width (illumination span) of the flashlamp in a normal direction relative to the conveyance direction. In an embodiment, the photonic processing operation can be manipulated by adjusting the overlap factor to compensate for variable heating characteristics of the material during the process. The overlap factor can have a value of OLF=0.6fw/v, where f is the pulse frequency, w is the beam width, and v is the speed of the material relative to the flash lamp, and at least the speed and pulse frequency can be manipulated.

In a further aspect, when the status parameter detection module is operatively coupled to a speed encoder and a thermal sensor, the photonic processing controller instructions are configured to, when executed by the photonic processing controller, execute a thermal calibration process for the material by actuating the conveyor system to move the material relative to the flashlamp and periodically pulsing the flashlamp in accordance with a first overlap factor, and periodically receiving thermal data for the material via the thermal sensor after each pulse of the flashlamp and associating the thermal data for the material with position data of the material derived from the position sensor of the conveyor system, comparing the associated data with temperature threshold criteria, and determining one or more adjustments for the operating parameters of the conveyor and the flashlamp in subsequent cycles for processing the material. The thermal data for the material can comprise signal data for multiple localized thermal readings on or around the material at a given point in time and/or at discrete positions relative to the flashlamp. The photonic processing controller instructions are further configured to, when executed by the photonic processing controller, execute a thermally-calibrated photonic processing cycle after a complete set of thermal data and position data is generated. The thermally-calibrated photonic processing cycle operates by actuating the conveyor system to move the material relative to the flashlamp and periodically pulsing the flashlamp in accordance with the overlap factor, wherein at least one of the velocity at which the conveyor system conveys the material, a flash duration of the flashlamp, a pulse frequency of the flashlamp, or a flash intensity of the flashlamp is adjusted between one or more pulses of the flashlamp as a function of the associated thermal data of the material relative to a predetermined reference criterion for the material. The thermally calibrated photonic processing cycle can be executed with or without the thermal sensor. In some embodiments, the thermally calibrated overlap factor can be modified as a function of the associated thermal data of the material relative to the predetermined reference criterion. The reference criterion can be a function of one more characteristics of the material, including a composition of the material, a thickness of the material, an area of the material in the plane of conveyance, a minimum processing temperature (e.g., a minimum necessary temperature for executing a photonic processing cycle), a maximum temperature (e.g., a temperature that causes irreparable damage to the process material or carrier), and a thermal distribution of the material in the plane of conveyance. Such characteristics of the material can be predetermined parameters input by a user or may be detected by artificial intelligence (“AI”) subsystems or with guided user input before or during the process.

In yet another aspect, when the temperature system remains connected to the photonic processing control system, the photonic processing controller instructions are configured to, when executed by the photonic processing controller, execute an adaptive thermally-calibrated photonic processing cycle by actuating the conveyor system to move the material relative to the flashlamp and periodically pulsing the flashlamp in accordance with the overlap factor, wherein intermediate thermal data is collected after each pulse and at least one of the velocity at which the conveyor system conveys the material, a flash duration of the flashlamp, a pulse frequency of the flashlamp, or an intensity of the flashlamp can be adjusted between one or more pulses of the flashlamp as a function of the associated intermediate thermal data of the material relative to a predetermined reference criterion for the material.

In yet other aspects, the control system is connected to a database that is adapted for storing the thermal data and associated data representing one or more of a composition of the material, a thickness of the material, an area of the material, and a position of the material relative to the flashlamp, and the photonic processing controller instructions are configured to, when executed by the photonic processing controller, execute an adaptive learning augmented photonic processing cycle relying on adaptive learning algorithms.

For purposes of illustration, programs and other executable program components, such as the operating system, are illustrated herein as discrete blocks. It is recognized, however, that such programs and components reside at various times in different storage components of a computing device, and are executed by one or more data processors of the device.

Embodiments of aspects of the inventions disclosed herein may be described in the general context of data and/or processor-executable instructions, such as program modules, stored one or more tangible, non-transitory storage media and executed by one or more processors/controllers or other devices. Generally, program modules include, but are not limited to, routines, programs, objects, components, and data structures that perform particular tasks or implement particular abstract data types. Aspects of the present disclosure may also be practiced in distributed computing environments where tasks are performed by remote processing devices that are linked through a communications network. In a distributed computing environment, program modules may be located in both local and remote storage media including memory storage devices.

In operation, processors, controllers, computers, and/or servers may execute the processor-executable instructions (or controller-executable instructions, e.g., software, firmware, and/or hardware) such as those illustrated herein to implement aspects of the invention.

Embodiments of aspects of the inventions disclosed herein may be implemented with processor-executable instructions. The processor-executable instructions may be organized into one or more processor-executable components or modules on a tangible processor readable storage medium. Aspects of the invention may be implemented with any number and organization of such components or modules. For example, aspects of the present disclosure are not limited to the specific processor-executable instructions or the specific components or modules illustrated in the figures and described herein. Other embodiments of the aspects of the invention may include different processor-executable instructions or components having more or less functionality than illustrated and described herein.

The order of execution or performance of the operations in embodiments of the aspects of the invention illustrated and described herein is not essential, unless otherwise specified. That is, the operations may be performed in any order, unless otherwise specified, and embodiments of the aspects of the invention may include additional or fewer operations than those disclosed herein. For example, it is contemplated that executing or performing a particular operation before, contemporaneously with, or after another operation is within the scope of aspects of the invention.

When introducing elements of aspects of the invention or the embodiments thereof, the articles “a,” “an,” “the,” and “said” are intended to mean that there are one or more of the elements. The terms “comprising,” “including,” and “having” are intended to be inclusive and mean that there may be additional elements other than the listed elements.

Not all of the depicted components illustrated or described may be required. In addition, some implementations and embodiments may include additional components. Variations in the arrangement and type of the components may be made without departing from the spirit or scope of the claims as set forth herein. Additional, different or fewer components may be provided and components may be combined. Alternatively or in addition, a component may be implemented by several components.

The above description illustrates the aspects of the inventions by way of example and not by way of limitation. This description enables one skilled in the art to make and use the aspects of the inventions, and describes several embodiments, adaptations, variations, alternatives and uses of the aspects of the inventions, including what is presently believed to be the best mode of carrying out the aspects of the invention. Additionally, it is to be understood that the aspects of the invention are not limited in application to the details of construction and the arrangement of components set forth in the description or illustrated in the drawings. The aspects of the invention are capable of other embodiments and of being practiced or carried out in various ways. Also, it will be understood that the phraseology and terminology used herein is for the purpose of description and should not be regarded as limiting.

While aspects of the present disclosure have been particularly shown and described with reference to example embodiments, it will be understood by those skilled in the art that various changes in form and detail may be made therein without departing from the spirit and scope of the disclosure.

Having described the disclosure in detail, it will be apparent that modifications and variations are possible without departing from the scope of the disclosure defined in the appended claims. For example, where specific dimensions are given, it is understood these dimensions are example and other dimensions are possible.

When introducing elements of the present disclosure or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the disclosure are achieved and other advantageous results attained.

As various changes could be made in the above systems and methods without departing from the scope of the disclosure, it is intended that all matter contained in the above description and shown in the accompanying drawings shall be interpreted as illustrative and not in a limiting sense.

### Other Statements of the Disclosure

The following are statements or features of invention described in the present disclosure. Some or all of the following statements may not be currently presented as claims. Nevertheless, the statements are believed to be patentable and may subsequently be presented as claims. Associated methods corresponding to the statements or apparatuses below, and products and apparatuses corresponding to the methods below, are also believed to be patentable and may subsequently be presented as claims. It is understood that the following statements may refer to and be supported by one, more than one, or all the embodiments described above.

A1. A method of photonically processing a set of material with a normalized thermal profile comprising:
providing a set of material carried on a support and an illumination system, the illumination system comprising a flashlamp defining an illumination region at least partially defined by a beam length of illumination pulses emitted by the flashlamp;
moving the set of material relative to the illumination region in a travel direction to expose the set of material to a plurality of overlapping illumination pulses emitted by the flashlamp to thermally process the set of material in an illumination sequence;
wherein the illumination sequence comprises exposing a downstream portion of the set of material to an earlier pulse and exposing an upstream portion of the set of material to a later pulse,
wherein a processing energy associated with exposing the upstream portion of the set of material to the later pulse is set as a function of a temporal heating characteristic measured in the upstream portion of the set of material associated with heat transfer after the downstream portion of the set of material is exposed to the earlier pulse.

A2. The method of statement A1, further comprising, prior to the illumination sequence, performing a calibration sequence to determine the temporal heating characteristic, wherein the calibration sequence comprises:
moving a preliminary set of material relative to the illumination region in the travel direction to expose the first set of material to a plurality of overlapping illumination pulses emitted by the flashlamp to thermally process the preliminary set of material;
exposing a downstream portion of the preliminary set of material to an earlier pulse and exposing an upstream portion of the preliminary set of material to a later pulse; and
after exposing the upstream portion of the preliminary set of material to the later pulse, measuring a thermal characteristic of the upstream portion of the preliminary set of material, associating the thermal characteristic with one or more operating parameters of the illumination pulses, and comparing the measured thermal characteristic and associated operating parameters with one or more reference criteria associated with an ideal energy level for processing the preliminary set of material.

A3. The method of statement A1, wherein the plurality of overlapping illumination pulses are administered as a function of a pulse frequency of the illumination pulses, a movement speed of the material relative to the illumination region in the travel direction, and the beam length.

A4. The method of statement A1, wherein the set of material is carried by a mobile support conveyed on a conveyor having a travel path that includes the illumination region.

A5. The method of statement A1, wherein the set of material comprises a plurality of electronics structures, each electronics structure comprising a thermal processing material to be processed by being exposed to the plurality of illumination pulses.

A6. The method of statement A5, wherein the plurality of electronics structures comprises a set of identical electronics structures arranged in an array spanning a first distance of the mobile support oriented in the travel direction.

What is claimed is:

1. A photonic processing apparatus for substantially uniform thermal processing of at least a first set of items, the photonic processing apparatus comprising:
a first mobile support configured to support the first set of items in a first item arrangement in which the items span a first distance, the first mobile support configured to support the first set of items in the first item arrangement for thermally processing the first set of items;
an illumination system configured to emit a plurality of illumination pulses in an illumination area, the illumination area having an illumination span that is less than the first distance; and
a control system comprising:
a photonic processing controller operatively connected to the illumination system; and
a tangible, non-transitory storage medium operatively connected to the photonic processing controller, the tangible, non-transitory storage medium storing controller-executable instructions configured to, when executed by the photonic processing controller, operate the illumination system to emit a plurality of illumination pulses to thermally process the first set of items as a position of the first set of items changes relative to the illumination system in a travel direction that corresponds to the illumination span of the illumination area to thermally process an entirety of the first set of items with the plurality of illumination pulses, wherein the operation of the illumination system is controlled as a function of a temporal heating characteristic associated with heat transfer through the mobile support to the first set of items upstream of the illumination area.

2. The photonic processing apparatus of claim 1, wherein the instructions for operating the illumination system comprise operating the illumination system to provide the plurality of illumination pulses as a function of the temporal heating characteristic, a pulse frequency of the illumination pulses, a rate of change of the position of the first set of items relative to the illumination area, and the illumination span.

3. The photonic processing apparatus of claim 2, wherein the instructions for operating the illumination system comprise operating the illumination system to provide the plurality of illumination pulses as a function of the temporal heating characteristic and an overlap factor based on the pulse frequency of the illumination pulses, rate of change of the position of the first set of items relative to the illumination area, and the illumination span.

4. The photonic processing apparatus of claim 3, wherein the overlap factor is further based on a constant value associated with the first set of items.

5. The photonic processing apparatus of claim 1:
wherein the temporal heating characteristic is associated with an increase in a temperature of an upstream portion of the first set of items after a downstream portion of the first set of items is exposed to a plurality of illumination pulses; and
wherein the operation of the illumination system comprises exposing the upstream portion of the first set of items to illumination pulses having a lower intensity than illumination pulses to which the downstream portion is exposed.

6. The photonic processing apparatus of claim 1, the control system further comprising a pyrometer operatively coupled to the photonic processing controller, the temporal heating characteristic being determined as a function of a signal generated by the pyrometer

7. The photonic processing apparatus of claim 6, wherein the pyrometer is positioned to detect thermal energy outside of the illumination area.

8. The photonic processing apparatus of claim 7, wherein the pyrometer is positioned to detect thermal energy upstream of the illumination area.

9. The photonic processing apparatus of claim 1, wherein the tangible, non-transitory storage medium further stores controller-executable instructions configured to operate the illumination system in a calibration sequence configured to determine the temporal heating characteristic.

10. The photonic processing apparatus of claim 9, wherein the tangible, non-transitory storage medium further stores controller-executable instructions configured to operate the illumination system in a calibrated thermal processing sequence based on the temporal heating characteristic.

11. The photonic processing apparatus of claim 10, wherein the tangible, non-transitory storage medium further stores controller-executable instructions configured to modify the operation of the illumination system as a function of a comparison of the temporal heating characteristic with a reference criterion stored in the tangible, non-transitory storage medium.

12. The photonic processing apparatus of claim 1, the photonic processing apparatus further comprising a conveyor operatively connected to the photonic processing controller and operable to move the first mobile support relative to the illumination system in the travel direction for changing the position of the first set of items relative to the illumination system.

13. The photonic processing apparatus of claim 1 in combination with the first set of items, wherein each item of the first set of items comprises a material configured to be thermally processed by exposure to illumination in the illumination region.

14. The photonic processing apparatus of claim 13, wherein the first set of items comprises a group of substantially identical items arranged in an array spanning the first distance.

15. The photonic processing apparatus of claim 1, wherein the first mobile support comprises a tray configured to carry the first set of items.

16. A method of photonically processing a set of items comprising:
providing a first mobile support configured to support the first set of items in a first item arrangement in which the items span a first distance, the first mobile support configured to support the first set of items in the first item arrangement for thermally processing the first set of items;
providing an illumination system configured to emit a plurality of illumination pulses in an illumination area, the illumination area having an illumination span that is less than the first distance;
changing a position of the first set of items relative to the illumination system in a travel direction that corresponds to the illumination span of the illumination area; and
using the thermal illumination system to emit a plurality of illumination pulses to thermally process an entirety of the first set of items with the plurality of illumination pulses;
wherein the illumination system is operated as a function of a temporal heating characteristic associated with heat transfer through the mobile support to the first set of items upstream of the illumination area.

17. The method of claim 16, wherein the illumination system is operated as a function of the temporal heating characteristic, a pulse frequency of the illumination pulses, a rate of change of the position of the first set of items relative to the illumination area, and the illumination span.

18. The method of claim 16, wherein the temporal heating characteristic is associated with an increase in a temperature of an upstream portion of the first set of items after a downstream portion of the first set of items is exposed to a plurality of illumination pulses, the method further comprising:
exposing the upstream portion of the first set of items to illumination pulses having a lower intensity than illumination pulses to which the downstream portion is exposed.

19. The method of claim 16, the photonic processing apparatus further comprising a conveyor operable to move the first mobile support relative to the illumination system in the travel direction for changing the position of the first set of items relative to the illumination system.

20. The method of claim 16, wherein the first set of items comprises a group of substantially identical items arranged in an array spanning the first distance.
